(19) United States
(12) Patent Application Publication
(10) Pub. No.: US 2024/0244930 A1
(43) Pub. Date: Jul. 18, 2024

(54) DISPLAY PANEL AND DISPLAY DEVICE

(71) Applicant: Hubei Yangtze Industrial Innovation Center Of Advanced Display Co., Ltd., Wuhan (CN)

(72) Inventors: Jiachang Gu, Wuhan (CN); Chujie Yu, Wuhan (CN); Kang Yang, Wuhan (CN)

(73) Assignee: Hubei Yangtze Industrial Innovation Center Of Advanced Display Co., Ltd., Wuhan (CN)

(21) Appl. No.: 18/618,576

(22) Filed: Mar. 27, 2024

(30) Foreign Application Priority Data
Oct. 24, 2023 (CN) 202311390228.1

(51) Int. Cl. H10K 59/80

(52) U.S. Cl. CPC H10K 59/873; H10K 59/80521

(57) ABSTRACT

A display panel includes a display region, an isolation region and a via region. The isolation region at least partially surrounds the via region, and the display region at least partially surrounds the isolation region. The display panel further includes a substrate, an isolation pillar, a cathode layer and a conductive structure. The isolation pillar is located in the isolation region, is located on a side of the substrate, and includes a metal material. The cathode layer is located on a side of the isolation pillar facing away from the substrate and is disconnected by the isolation pillar. The conductive structure is located between the cathode layer and the substrate and includes at least one conductive portion, the conductive portion is at least partially located in the isolation region and overlaps with an edge of the via region.

### CROSS-REFERENCE TO RELATED APPLICATION

This application claims priority to Chinese Patent Application No. CN 202311390228.1, filed on Oct. 24, 2023, the disclosure of which is incorporated herein by reference in its entirety.

### TECHNICAL FIELD

The present disclosure relates to the field of display technologies, and in particular to, a display panel and a display device.

### BACKGROUND

In an existing display panel, a via region is usually disposed at the intermediate position, and a cathode layer at a cutting edge of the via region is exposed. When static electricity exists in the via region, the static electricity will be transmitted to the display region through the cathode layer exposed at the cutting edge, so that a penetrating damage is caused and further, a film layer is peeled off, and thus the encapsulation fails.

### SUMMARY

Embodiments of the present disclosure provide a display panel and a display device, so as to reduce static electricity to the cathode layer, and thus reduce the risk of encapsulation failure of the display panel.

In a first aspect, an embodiment of the present disclosure provides a display panel. The display panel includes a display region, an isolation region and a via region. The isolation region at least partially surrounds the via region, and the display region at least partially surrounds the isolation region. The display panel further includes a substrate, an isolation pillar, a cathode layer and a conductive structure. The isolation pillar is located in the isolation region, is located on a side of the substrate, and includes a metal material. The cathode layer is located on a side of the isolation pillar facing away from the substrate and is disconnected by the isolation pillar. The conductive structure is located between the cathode layer and the substrate and includes at least one conductive portion, the conductive portion is at least partially located in the isolation region and overlaps with an edge of the via region.

In a second aspect, an embodiment of the present disclosure further provides a display device including the display panel described in the first aspect.

### BRIEF DESCRIPTION OF DRAWINGS

FIG. 1 is a top structural schematic view of a display device according to an embodiment of the present disclosure;

FIG. 2 is an enlarged schematic view of a region A according to an embodiment of the present disclosure;

FIG. 3 is a cross-sectional view along an AA′ direction in FIG. 2;

FIG. 4 is another enlarged schematic view of a region A in FIG. 1;

FIG. 5 is another enlarged schematic view of a region A in FIG. 1;

FIG. 6 is another enlarged schematic view of a region A in FIG. 1;

FIG. 7 is another enlarged schematic view of a region A in FIG. 1;

FIG. 8 is another enlarged schematic view of a region A in FIG. 1;

FIG. 9 is another enlarged schematic view of a region A in FIG. 1;

FIG. 10 is a cross-sectional view along a BB′ direction in FIG. 9;

FIG. 11 is a schematic view of a circuit structure of a pixel driving circuit according to an embodiment of the present disclosure;

FIG. 12 is a top structural schematic view of a pixel driving circuit according to an embodiment of the present disclosure;

FIG. 13 is another enlarged schematic view of a region A in FIG. 1;

FIG. 14 is a cross-sectional view along a CC′ direction in FIG. 13;

FIG. 15 is another enlarged schematic view of a region A in FIG. 1;

FIG. 16 is a cross-sectional view along a DD′ direction in FIG. 15;

FIG. 17 is another cross-sectional view along a BB′ direction in FIG. 9; and

FIG. 18 is a schematic structural view of a display device according to an embodiment of the present disclosure.

### DETAILED DESCRIPTION

In order to make the objectives, technical schemes and advantages of the present disclosure clearer, the technical schemes of the present disclosure will be fully described below by using specific implementations in conjunction with the accompanying drawings in embodiments of the present disclosure. Apparently, the described embodiments are part of, but not all, the embodiments of the present disclosure. All other embodiments obtained by those of ordinary skill in the art based on the embodiments of the present disclosure without needing creative efforts shall all fall in the scope of protection of the present disclosure.

The research shows that in a display panel, an isolation pillar is usually used in an isolation region close to a via region so as to improve the blocking effect for moisture and oxygen, the isolation pillar is made of metal, one end of a cathode layer is exposed at a cutting edge, another end of the cathode layer extends to a display region, and is disconnected at the position of the isolation pillar. When static electricity exists in the via region, since the isolation pillar connects the disconnected cathodes together so as to form a complete conductive path, the static electricity may be transmitted to the display region through the cathode layer exposed at the cutting edge, so that a penetrating damage is caused, and further, a film layer is peeled off, and thus the encapsulation fails.

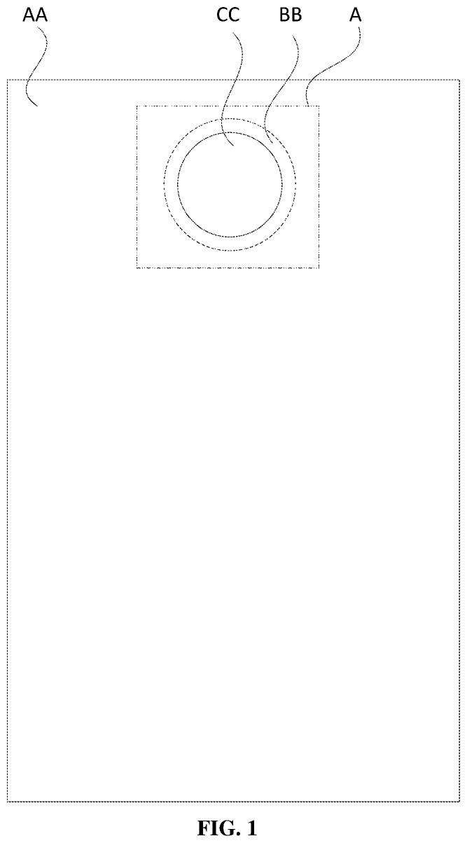

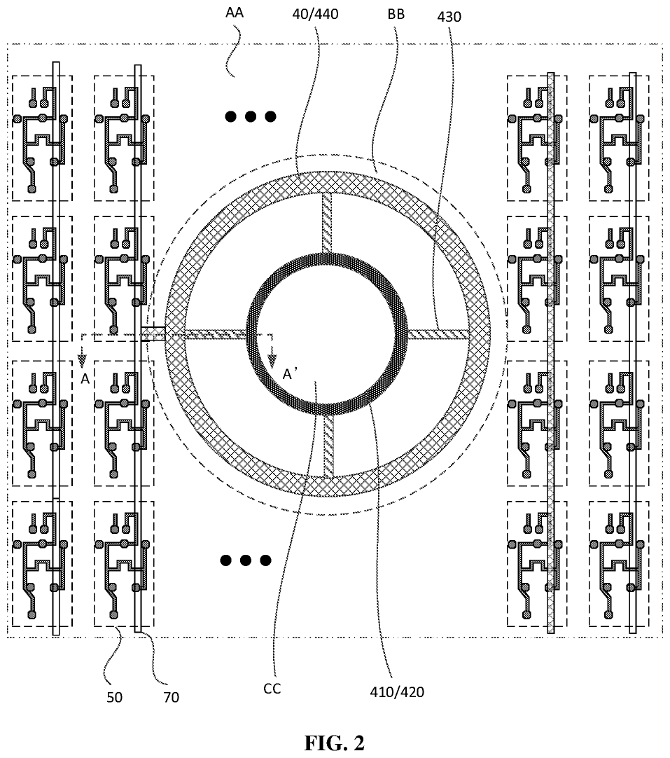

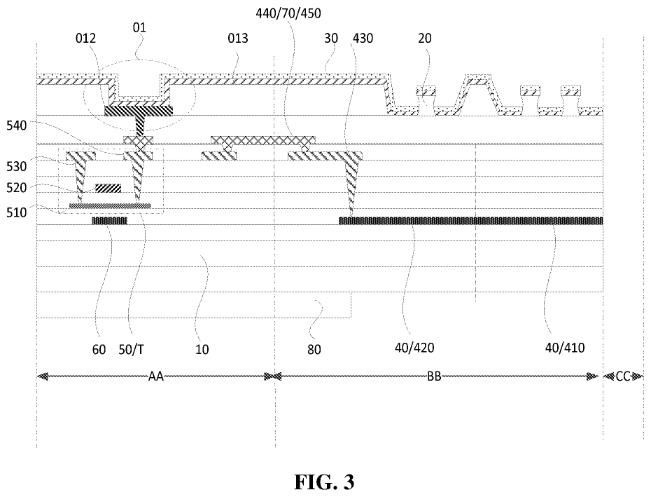

FIG. 1 is a top structural schematic view of a display device according to an embodiment of the present disclosure. FIG. 2 is an enlarged schematic view of a region A according to an embodiment of the present disclosure; and FIG. 3 is a cross-sectional view along an AA′ direction in FIG. 2. Referring to FIGS. 1 to 3, a display panel provided in an embodiment of the present disclosure includes a display region AA, an isolation region BB and a via region CC. The isolation region BB at least partially surrounds the via region CC, and the display region AA at least partially surrounds the isolation region BB. The display panel further includes a substrate 10, an isolation pillar 20, a cathode layer 30, and a conductive structure 40. The isolation pillar 20 is located in the isolation region BB, and the isolation pillar 20 is located on a side of the substrate 10. The isolation pillar 20 includes a metal material. The isolation pillar 20 has conductivity. The cathode layer 30 is located on a side of the isolation pillar 20 facing away from the substrate 10, and the cathode layer 30 is disconnected by the isolation pillar 20 so as to cut a propagation path of moisture and oxygen propagating along the cathode layer 30 to the display region AA. The conductive structure 40 is located between the cathode layer 30 and the substrate 10, and includes at least one conductive portion 410. The conductive portion 410 is at least partially located in the isolation region BB, and the conductive portion 410 overlaps with an edge of the via region CC. The conductive portion 410 extends to the edge of the via region CC so that an edge of the conductive portion 410 are flush with the edge of the via region CC. The conductive portion 410 is exposed at a position of the edge of the via region CC. The edge of the via region CC refers to the boundary between the via region CC and the isolation region BB.

According to the embodiments of the present disclosure, the conductive structure 40 is located between the cathode layer 30 and the substrate 10, and the conductive structure 40 includes the at least one conductive portion 410. When static electricity is generated on the side of the substrate 10 in the via region CC, the static electricity propagates in a direction towards the cathode layer 30 in the via region CC. Since the conductive structure 40 is disposed between the cathode layer 30 and the substrate 10, the conductive portion 410 of the conductive structure 40 extends to the edge of the via region CC, the static electricity reaches the conductive portion 410 firstly before the static electricity reaches the cathode layer 30. That is, the static electricity firstly reaches the conductive portion 410 closer to the substrate 10, and then at least a part of the static electricity is discharged through the conductive portion 410, thereby reducing the amount of static electricity finally reaching the cathode layer 30, avoiding the problem of film layer peeling due to the penetrating damage caused by excessive static electricity transmitted from the cathode layer 30 to the display region AA, and reducing the risk of encapsulation failure of the display panel.

It should be noted that in FIG. 2, exemplarily, the conductive structure 40 including one conductive portion 410 is used as an example for description, which is not limited thereto. In other embodiments, the conductive structure 40 may include multiple conductive portions 410. Moreover, in FIG. 2, exemplarily, the via region CC being a circular region is used as an example, which is not limited thereto, and in other embodiments, the via region CC may also be a square region, a trapezoid region, and the like.

It should also be noted that in FIG. 3, exemplarily, the conductive portion 410 locating in the isolation region BB is used as an example for description, which is not limited thereto. In other embodiments, the conductive portion 410 may be located in the isolation region BB and display region AA.

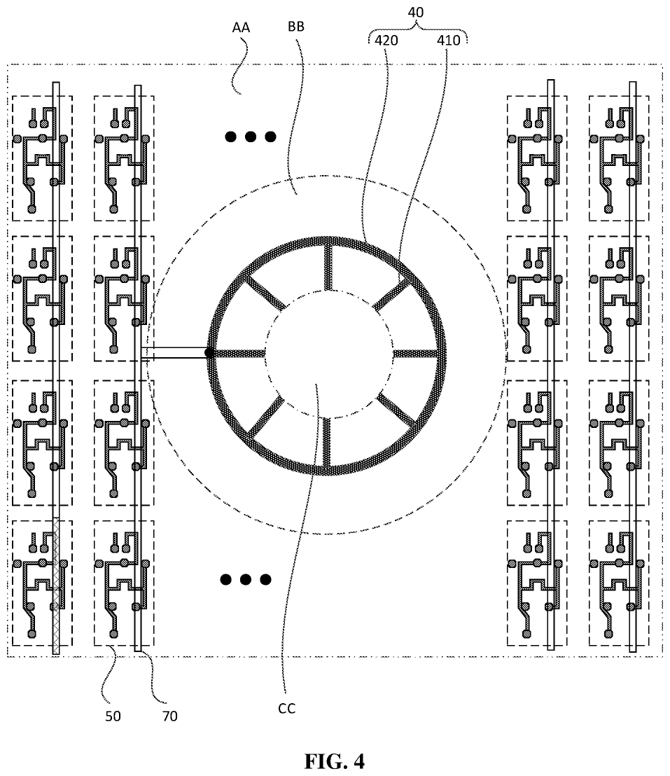

FIG. 4 is another enlarged schematic view of a region A in FIG. 1. As shown in FIG. 4, the conductive structure 40 includes multiple conductive portions 410 and a first connection portion 420. The multiple conductive portions 410 are arranged at intervals along an extension direction of the edge of the via region CC. In the embodiment shown in FIG. 4, the edge of the via region CC is circular, and the multiple conductive portions 410 are arranged in a circular shape around the via region CC. In other embodiments, for example, the edge of the via region CC is square, and the multiple conductive portions 410 are arranged in a square shape around the via region CC. The first connection portion 420 is located in the isolation region BB, the first connection portion 420 is located on a side of the conductive portion 410 facing away from the via region CC, and the first connection portion 420 is located between the conductive portion 410 and the display region AA. The first connection portion 420 is electrically connected to the multiple conductive portions 410.

Exemplarily, as shown in FIG. 4, a circular dashed line having a smaller radius is shown as the edge of the via region CC, and the multiple conductive portions 410 are arranged at intervals in the extension direction of the edge of the via region CC. The conductive portion 410 serves as a static electricity contact point for receiving static electricity of the via region CC and conducting the static electricity away through the first connection portion 420 electrically connected to the conductive portion 410, thereby reducing the amount of static electricity finally reaching the cathode layer 30. The multiple conductive portions 410 are disposed at intervals at the position of the edge of the via region CC so that multiple static electricity contact points exist at the position of the edge of the via region CC, in this way, static electricity generated on the side of the substrate 10 in the via region CC may be firstly received by at least one conductive portion of the multiple conductive portions 410 and discharged by the first connection portion 420, whereby more static electricity may be discharged through the conductive structure 40, thereby further reducing the amount of static electricity finally reaching the cathode layer 30, improving the static electricity discharge capability of the conductive structure 40, and further reducing the risk of encapsulation failure of the display panel.

In an embodiment, since the conductive structure 40 is located in the isolation region BB close to the via region CC, the conductive structure 40 is easily deformed by the erosion of moisture and oxygen in the via region CC. The conductive structure 40 includes multiple conductive portions 410, and the multiple conductive portions 410 are arranged at intervals in the extension direction of the edge of the via region CC. In the multiple conductive portions 410 arranged at intervals, the space between two adjacent conductive portions 410 is not deformed due to the erosion of moisture and oxygen in the via region CC, and a deformation space can be provided for a conductive portion 410 which is deformed due to the erosion of moisture and oxygen, thereby reducing the influence of the deformation on the film layers, reducing the risk of the film layer being peeled off, and thus improving the encapsulation capability of the display panel.

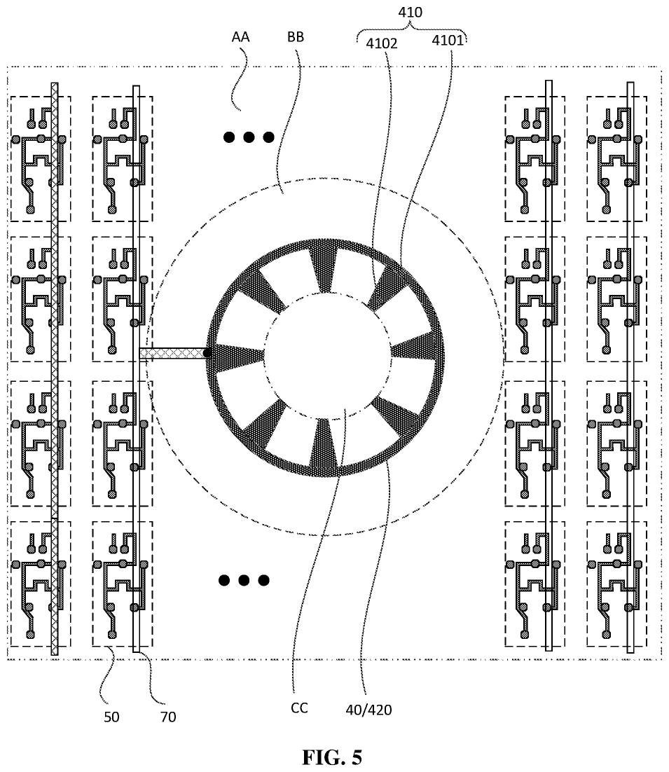

FIG. 5 is another enlarged schematic view of a region A in FIG. 1. As shown in FIG. 5, the conductive portion 410 includes a conductive connection end 4101 and a conductive tip end 4102. The conductive connection end 4101 connects the conductive tip end 4102 with the first connection portion 420. The conductive connection end 4101 and the conductive tip end 4102 are different portions of the conductive portion 410. The conductive connection end 4101 is a portion of the conductive portion 410 close to the first connection portion 420. The conductive tip end 4102 is a portion of the conductive portion 410 facing away from the first connection portion 420. In a direction perpendicular to an extension direction of the conductive portion 410, a width of the conductive tip end 4102 is less than a width of the conductive connection end 4101.

Exemplarily, the conductive tip end 4102 is located at a position of the conductive portion 410 facing the via region CC, and the conductive tip end 4102 of the conductive portion 410 is exposed at the position of the edge of the via region CC. The conductive connection end 4101 is located at a position of the conductive portion 410 facing the first connection portion 420 so as to connect the conductive tip end 4102 to the first connection portion 420. When the conductive tip end 4102 receives static electricity, the static electricity is transmitted to the first connection portion 420 through the conductive connection end 4101, and then the static electricity is discharged through the first connection portion 420. Since the conductive tip end 4102 is a position of the conductive portion 410 that contacts static electricity, so that in the direction perpendicular to the extension direction of the conductive portion 410, the width of the conductive tip end 4102 is less than the width of the conductive connection end 4101. The principle of “tip discharge”, which means that charges more easily aggregate on the place with large curvature on the surface of the object (such as a top end of a sharp and small object) is used, so that the conductive tip end 4102 is more likely to attract static electricity generated from the side of the substrate 10 in the via region CC, thereby reducing static electricity finally reaching the cathode layer 30, improving the static electricity discharge capability of the conductive structure 40, and further reducing the risk of encapsulation failure of the display panel.

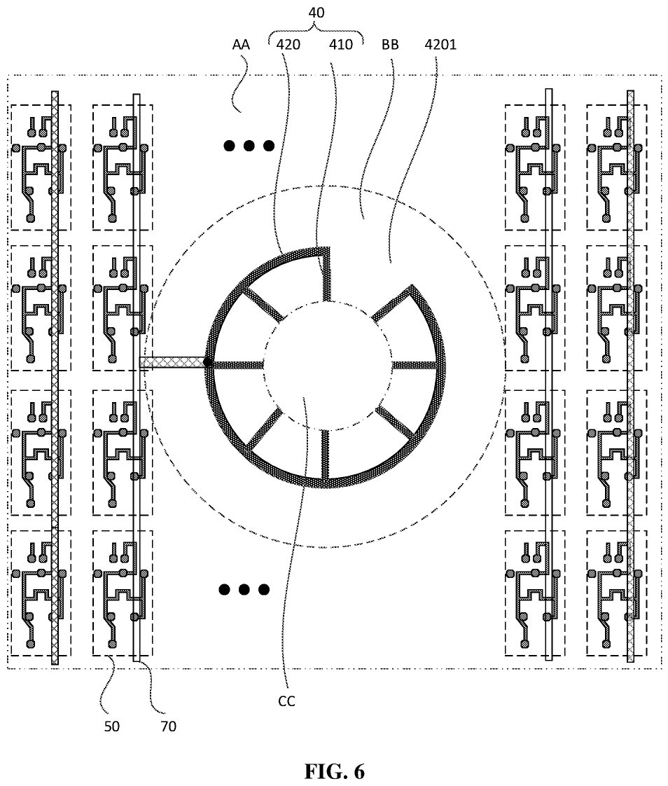

FIG. 6 is another enlarged schematic view of a region A in FIG. 1. As shown in FIG. 6, the first connection portion 420 extends in the extension direction of the edge of the via region CC. The first connection portion 420 includes a first notch 4201. In the embodiment shown in FIG. 6, the first connection portion 420 has a ring-shaped structure with one first notch 4201, and the multiple conductive portions 410 are located within the ring-shaped structure and electrically connected to the first connection portion 420. Here, the first notch 4201 maybe located at a position corresponding to a spacing between two adjacent conductive portions 410 in the first connection portion 420, that is, in a direction in which the via region CC points towards the isolation region BB, and the first notch 4201 and the conductive portion 410 are staggered.

Exemplarily, as shown in FIG. 6, the conductive structure 40 is located at a position of the isolation region BB facing the via region CC, and the multiple conductive portions 410 are connected to the first connection structure 420. The moisture and oxygen in the via region CC may be eroded into the first connection structure 420 along the conductive portions 410 or the space between adjacent conductive portions 410, so that the first connection structure 420 is deformed, thereby affecting the structure of each film layer. For this reason, the first notch 4201 is disposed on the first connection structure 420, a position where the first notch 4201 is located is not deformed due to the erosion of moisture and oxygen in the via region CC, and the first notch 4201 can provide a deformation space for the first connection portion 420 deformed due to the erosion of moisture and oxygen, thereby reducing the influence of deformation on the film layers, reducing the risk of the film layer being peeled off, and thus improving the encapsulation capability of the display panel.

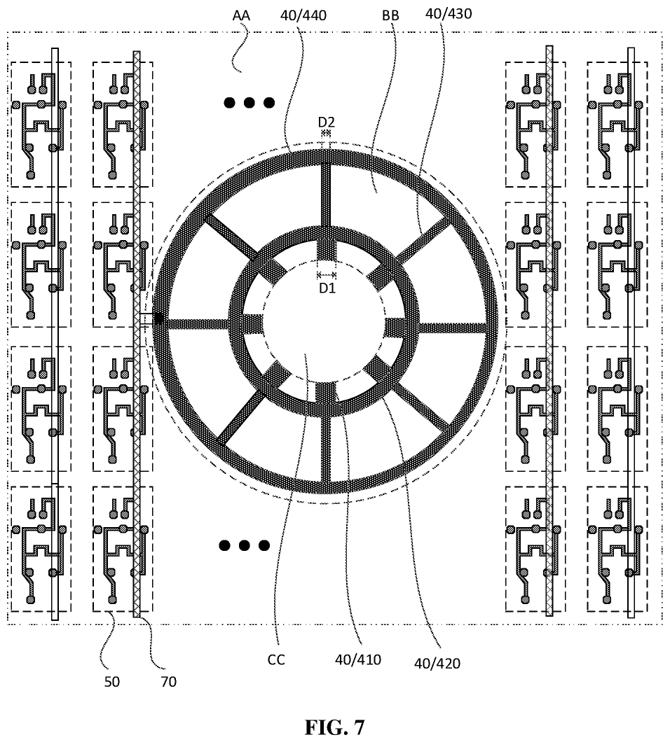

FIG. 7 is another enlarged schematic view of a region A in FIG. 1. As shown in FIG. 7, the conductive structure 40 further includes multiple connection spokes 430 and a second connection portion 440. The second connection portion 440 at least partially surrounds the first connection portion 420, and the connection spokes 430 connect the first connection portion 420 and the second connection portion 440. In the embodiment shown in FIG. 7, the second connection portion 420 is located in the isolation region BB, and the second connection portion 440 is located on a side of the first connection portion 420 facing away from the conductive portion 410, the multiple connection spokes 430 are located between the first connection portion 420 and the second connection portion 440, and the multiple connection spokes 430 are arranged at intervals in an extension direction of the first connection portion 420.

Exemplarily, as shown in FIG. 7, the multiple connection spokes 430 extend in a radial direction and are arranged at intervals in a circumferential direction. The circumferential direction is the extension direction of the first connection portion 420, and the radial direction is the direction in which the via region CC points towards the isolation region BB. The radial direction is perpendicular to the circumferential direction. The conductive portion 410 is electrically connected to the first connection portion 420. The first connection portion 420 is electrically connected to the second connection portion 440 by means of the multiple connection spokes 430, and thus the static electricity received by the conductive portion 410 may be conducted away by means of the first connection portion 420, the spokes 430 and the second connection portion 440, so as to discharge the static electricity. For this reason, the connection spoke 430 and the second connection portion 440 serve as lead-out lines to conduct away the static electricity on the first connection portion 420 and the conductive portion 410.

Exemplarily, referring to FIG. 7, a number of connection spokes 430 is equal to a number of conductive portions 410. In the radial direction, the connection spokes 430 are collinear with the conductive portions 410 in one-to-one correspondence with the connection spokes 430. The static electricity propagated from the via region CC towards the isolation region BB propagates along the conductive portions 410 and the connection spokes 430 which are in one-to-one correspondence and collinear, thereby reducing the length of the propagation path of the static electricity, and improving the propagation capability of the static electricity. In other embodiments, a number of connection spokes 430 may not be equal to a number of conductive portions 410, or the connection spokes 430 and the conductive portions 410 may not be collinear.

On the basis of the above-described embodiments, with continued reference to FIG. 7, in a direction perpendicular to an extension direction of the conductive portions 410, a width of a conductive portion of the multiple conductive portions 410 is a first width D1. In a direction perpendicular to an extension direction of the multiple connection spokes 430, a width of a connection spoke of the multiple connection spokes 430 is a second width D2. The first width D1 is greater than the second width D2. Since exposed part of the conductive portion 410 at the position of the edge of the via region CC is used for receiving static electricity, and the first width D1 is set to be greater than the second width D2, that is, in the direction perpendicular to the extension direction of the conductive portion 410, a width of the exposed part of the conductive portion 410 at the position of the edge of the via region CC is larger, whereby the contact area of the conductive portion 410 for receiving static electricity is increased, so that the conductive portion 410 receives more static electricity generated from the side of the substrate 10 in the via region CC, the amount of static electricity finally reaching the cathode layer 30 is further reduced, the static electricity discharge capability of the conductive structure 40 is improved, and thus the risk of encapsulation failure of the display panel is reduced.

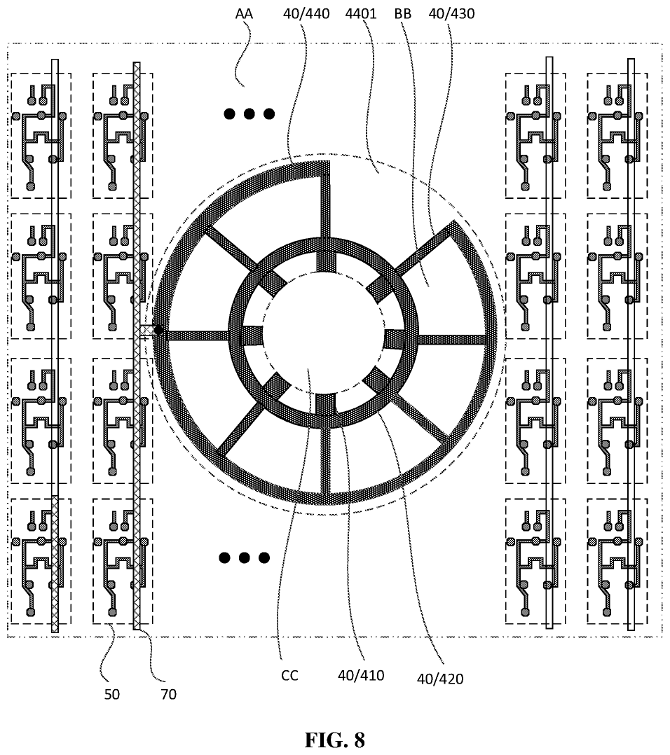

FIG. 8 is another enlarged schematic view of a region A in FIG. 1. As shown in FIG. 8, the second connection portion 440 extends in the extension direction of the edge of the via region CC and includes a second notch 4401. In the embodiment shown in FIG. 8, the second connection portion 440 has a ring-shaped structure provided with one second notch 4401. In other embodiments, for example, the second connection portion 440 may include multiple second notches 4401. The second notch 4402 maybe located at a position corresponding to a spacing between two adjacent connection spokes 430 in the second connection portion 440, that is, in the direction in which the via region CC points towards the isolation region BB, and the second notch 4401 and the connection spoke 430 are staggered.

Exemplarily, as shown in FIG. 8, the via region CC is easily eroded by moisture and oxygen, and the moisture and oxygen in the via region CC may be eroded into the second connection portion 440 along the conductive portion 410, the first connection portion 420 and the connection spoke 430, or the moisture and oxygen may be eroded into the second connection portion 440 along the space between adjacent conductive portions 410 and the space between adjacent connection spokes 430, so that the second connection structure 440 is deformed, thereby affecting the structure of each film layer. For this reason, the second notch 4401 is disposed on the second connection structure 420, a position where the second notch 4401 is located is not deformed due to the erosion of moisture and oxygen in the via region CC, and the second notch 4401 can provide a deformation space for the second connection portion 440 deformed due to the erosion of moisture and oxygen, thereby further reducing the influence of deformation on the film layers, reducing the risk of the film layer being peeled off, and thus improving the encapsulation capability of the display panel.

On the basis of the above-described embodiments, with continued reference to FIG. 2, the conductive structure 40 includes one conductive portion 410, and the conductive portion 410 extends in the extension direction of the edge of the via region CC. The conductive structure 40 includes one conductive portion 410, the conductive portion 410 forms an ring-shaped structure or a ring-like structure around the via region CC, and a continuous conductive portion 410 is exposed at the position of the edge of the via region CC, whereby the contact area of the conductive portion 410 for receiving the static electricity is increased, so that the conductive portion 410 receives more static electricity generated from the side of the substrate 10 in the via region CC, the amount of static electricity finally reaching the cathode layer 30 is further reduced, the static electricity discharge capability of the conductive structure 40 is improved, and thus the risk of encapsulation failure of the display panel is reduced. The ring-like structure includes, for example, a structure formed after a notch is disposed on the ring-like structure.

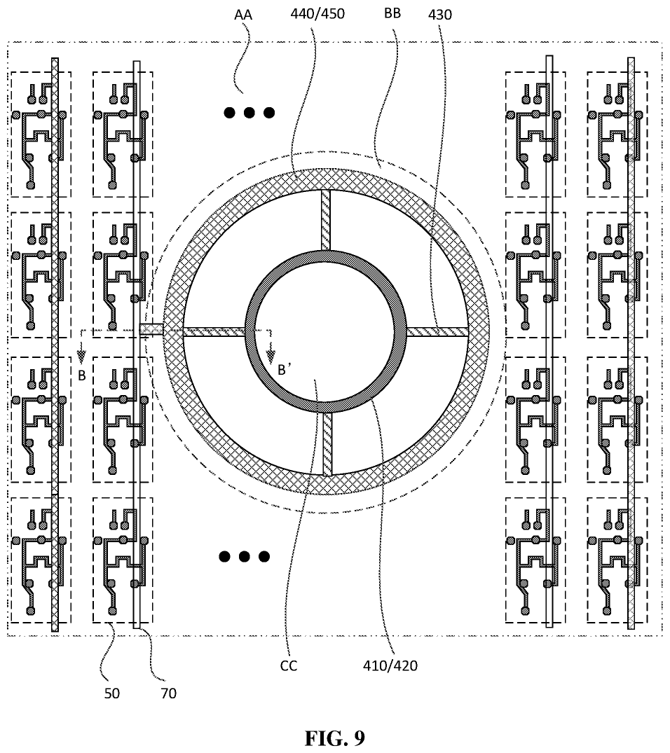

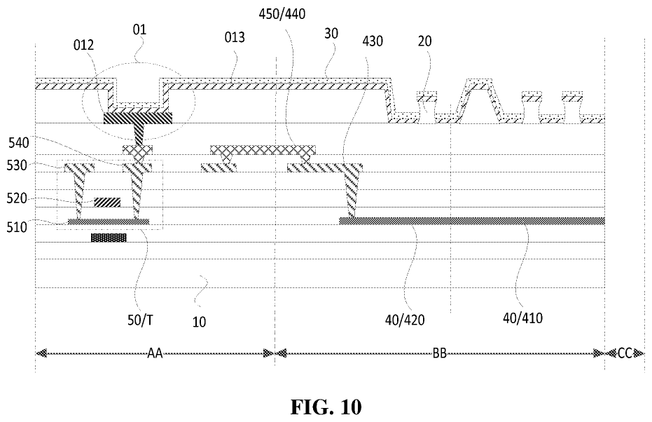

FIG. 9 is another enlarged schematic view of a region A in FIG. 1, and FIG. 10 is a cross-sectional view along a BB′ direction in FIG. 9. Referring to FIGS. 9 and 10, the conductive portion 410 includes a semiconductor material. The semiconductor material may include amorphous silicon, polysilicon, metal oxide semiconductor, and the like. The semiconductor material is used as the conductive material of the conductive portion 410. On the one hand, a resistance of the semiconductor material is greater than a resistance of the metal material, that is, the conductive capability of the semiconductor material is less than the conductive capability of the metal material. Thus, the heat generated by static electricity on the conductive portion 410 can be reduced, so that the heat generated by static electricity formed on the conductive portion 410 is prevented from being excessively large to cause the film layer damage. On the other hand, the stability of the semiconductor material is better than the stability of the metal material, that is, the capability of the semiconductor material for resisting the erosion of moisture and oxygen is stronger, whereby the conductive portion 410 adjacent to the via region CC is provided with the semiconductor material, so that the risk that the conductive portion 410 is deformed due to the erosion of moisture and oxygen can be reduced, the influence of the deformation of the conductive portion 410 on each film layer is further reduced, the risk of the film layer being peeled off is reduced, and the encapsulation capacity of the display panel is improved.

Optionally, referring to FIGS. 9 and 10, the display panel includes multiple pixel driving circuits 50, at least a part of the multiple pixel driving circuits 50 is located in the display region AA. The pixel driving circuit 50 is located between the cathode layer 30 and the substrate 10. In a direction perpendicular to a plane where the substrate 10 is located, and the conductive portion 410 is between the substrate 10 and the pixel driving circuits 50.

Exemplarily, as shown in FIG. 10, the display panel includes multiple light-emitting elements 01 and multiple pixel driving circuits 50, and the light-emitting element 01 is located in the display region AA. The light-emitting element 01 is electrically connected to the pixel driving circuit 50 located in the display region AA, and the light-emitting element 01 is driven by the pixel driving circuit 50 to emit light for display. The pixel driving circuit 50 is located on a side of substrate 10, and the pixel driving circuit 50 is closer to the substrate 10 than the cathode layer 30. Alternatively, it should be understood that that display panel includes a driver circuit layer, the driver circuit layer is located between the substrate 10 and the cathode layer 30, and the multiple pixel driving circuits 50 are located at the driver circuit layer. Exemplarily, in the direction perpendicular to the plane where the substrate 10 is located, the conductive portion 410 portion 410 may be located at the film layer of the driver circuit layer, the driver circuit layer is located between the substrate 10 and the cathode layer 30, and exemplarily, each film layer in the driver circuit layer is closer to the substrate 10 than the cathode layer 30. When the static electricity is generated on the side of the substrate 10 in the via region CC, the static electricity propagates in the direction towards the cathode layer 30 in the via region CC. Since each film layer in the driver circuit layer is closer to the substrate 10 than the cathode layer 30, the conductive portion 410 located at the film layer of the driver circuit layer is firstly reached before the static electricity reaches the cathode layer 30, and at least a part of static electricity is discharged through the conductive portion 410, thereby reducing the amount of static electricity finally reaching the cathode layer 30. In an embodiment, the conductive portion 410 is located between the substrate 10 and the pixel driving circuit 50, it is ensured that static electricity generated on the side of the substrate 10 in the via region CC can be firstly discharged at the conductive portion 410.

On the basis of the above-described embodiments, with continued reference to FIG. 10, the display panel includes multiple pixel driving circuits 50, and at least a part of the multiple pixel driving circuits 50 is located in the display region AA. The pixel driving circuits 50 are located between the cathode layer 30 and the substrate 10. The pixel driving circuit 50 includes a thin-film transistor T, and the thin-film transistor T includes a channel layer 510, a gate 520, a source 530 and a drain 540. The conductive portion 410 and the channel layer 510 are disposed in a same layer.

Exemplarily, the display panel includes a driver circuit layer. The driver circuit layer is located between the substrate 10 and the cathode layer 30 and includes multiple pixel driving circuits 50 for driving the light-emitting element 01. Each pixel driving circuit 50 includes at least one thin-film transistor T, and the structure of the at least one thin-film transistor T may be a top gate structure or a bottom gate structure. Here, the structure of the at least one thin-film transistor T is not limited. For example, as shown in FIG. 10, if the structure of the at least one thin-film transistor T is the top gate structure, then in a direction in which the substrate 10 points towards the cathode layer 30, the driver circuit layer includes an active layer (a channel layer 510), a first insulating layer, a gate metal layer (a gate 520), a second insulating layer, and a source-drain metal layer (a source 530 and a drain 540) which are sequentially stacked. The thin-film transistor T includes a channel layer 510, a gate 520, a source 530 and a drain 540, where the channel layer 510 of the thin-film transistor T is located at the active layer, the gate 520 of thin-film transistor T is located at the gate metal layer, and the source 530 and the drain 540 of the thin-film transistor T are located at the source-drain metal layer. In this way, the conductive portion 410 and the channel layer 510 disposed in a same layer, on the one hand, the channel layer 510 is located at the film layer of the driver circuit layer, and the conductive portions 410 disposed in the same layer as the channel layer 510 are closer to the substrate 10 than the cathode layer 30; therefore before the static electricity reaches the cathode layer 30, the static electricity firstly reaches the conductive portion 410 in the film layer of the driver circuit layer, and at least a part of the static electricity is discharged through the conductive portion 410, so that the amount of static electricity finally reaching the cathode layer 30 is reduced. On the other hand, the material used for the channel layer 510 is also the semiconductor material, during fabrication, the conductive portion 410 and the channel layer 510 may be formed in a same fabrication process by using a same mask, without separately preparing a semiconductor material at the position where the conductive portion 410 is located, thereby saving the cost, reducing the number of processes, and improving the production efficiency.

It should be noted that in the embodiments of the present disclosure, exemplarily, the conductive portion 410 and the channel layer 510 disposed in a same layer is used as an example, which is not limited thereto. In other embodiments, the conductive portion 410 and the gate 520 may also be disposed in a same layer, or the conductive portion 410 and the source 530, or the conductive portion 410 and the drain 540 may also be disposed in a same layer.

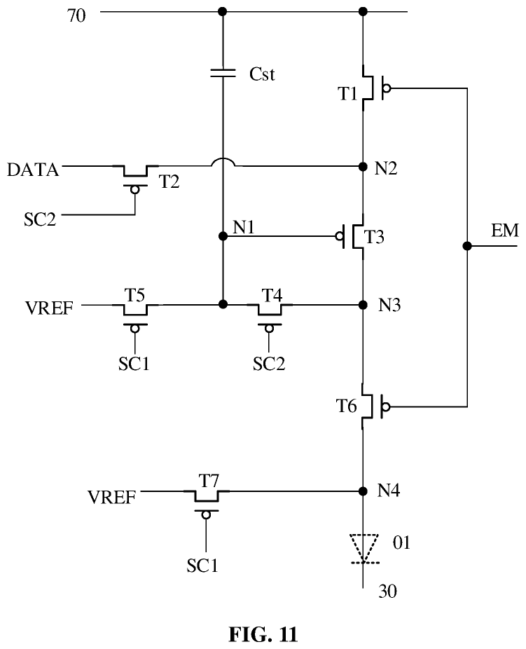

FIG. 11 is a schematic view of a circuit structure of a pixel driving circuit according to an embodiment of the present disclosure. Referring to FIG. 11, the pixel driving circuit includes multiple thin-film transistors T. The multiple thin-film transistor T include a power supply write transistor T1, a data write transistor T2, a drive transistor T3, a compensation transistor T4, a first reset transistor T5, a light-emitting control transistor T6 and a second reset transistor T7. The pixel driving circuit further includes a storage capacitor Cst. A first electrode of the power supply write transistor T1 is electrically connected to the power supply voltage line 70, a second electrode of the power supply write transistor T1 is electrically connected to the second node N2, and a gate of the power supply write transistor T1 is electrically connected to a light-emitting control scan signal line EM. The power supply voltage line 70 is configured to supply a positive power supply voltage. A first electrode of the data write transistor T2 is electrically connected to a data line DATA, a second electrode of the data write transistor T2 is electrically connected to a second node N2, and a gate of the data write transistor T2 is electrically connected to a second scan signal line SC2. A first electrode of the drive transistor T3 is electrically connected to the second node N2, a second electrode of the drive transistor T3 is electrically connected to a third node N3, and a gate of the drive transistor T3 is electrically connected to the first node N1. A first electrode of the compensation transistor T4 is electrically connected to the first node N1, a second electrode of the compensation transistor T4 is electrically connected to the third node N3, and a gate of the compensation transistor T4 is electrically connected to the second scan signal line SC2. A first electrode of the first reset transistor T5 is electrically connected to the first node N1, a second electrode of the first reset transistor T5 is electrically connected to a reset signal line VREF, and a gate of the first reset transistor T5 is electrically connected to a first scan signal line SC1. A first electrode of the light-emitting control transistor T6 is electrically connected to the third node N3, a second electrode of the light-emitting control transistor T6 is electrically connected to a fourth node N4, and a gate of the light-emitting control transistor T6 is electrically connected to the light-emitting control scan signal line EM. A first electrode of the second reset transistor T7 is electrically connected to the fourth node N4, a second electrode of the second reset transistor T7 is electrically connected to the reset signal line VREF, and a gate of the second reset transistor T7 is electrically connected to the first scan signal line SC1. A first plate of the storage capacitor Cst is electrically connected to the first node N1, and a second plate of the storage capacitor Cst is electrically connected to the power supply voltage line 70. The light-emitting element 01 is connected to the fourth node N4.

The first node N1, the second node N2, the third node N3 and the fourth node N4 may be imaginary connection nodes, or may be physical connection nodes.

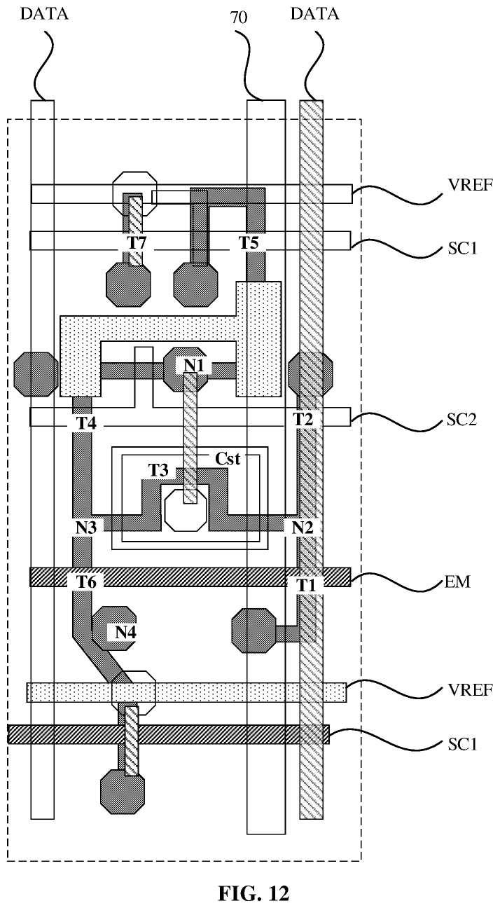

FIG. 12 is a top structural schematic view of a pixel driving circuit according to an embodiment of the present disclosure. Referring to FIGS. 11 and 12, in the field of display technologies, devices such as the thin-film transistor T and the storage capacitor Cst in the pixel driving circuit are all achieved by stacking film layers. The display panel includes a silicon semiconductor layer, a first metal layer, a capacitance metal layer, a second metal layer and a third metal layer laminated in sequence. The silicon semiconductor layer may include an oxide semiconductor material. The light-emitting control scan signal line EM, the first scan signal line SC1, the second scan signal line SC2, and the first plate of the storage capacitor Cst are located at the first metal layer. The first plate of the storage capacitor Cst is reused as a gate of the drive transistor T3, and the second plate of the storage capacitor Cst is opposite to the first plate of the storage capacitor Cst. The second plate of the storage capacitor Cst and the reset signal line VREF are located at the capacitance metal layer. The data line DATA is located on the second metal layer. The power supply voltage line 70 is located at the third metal layer. A gate of the thin-film transistor T is a part where the scan signal line overlaps with a semiconductor wiring in the silicon semiconductor layer. The scan signal line may include a light-emitting control scan signal line EM, a first scan signal line SC1 and a second scan signal line SC2.

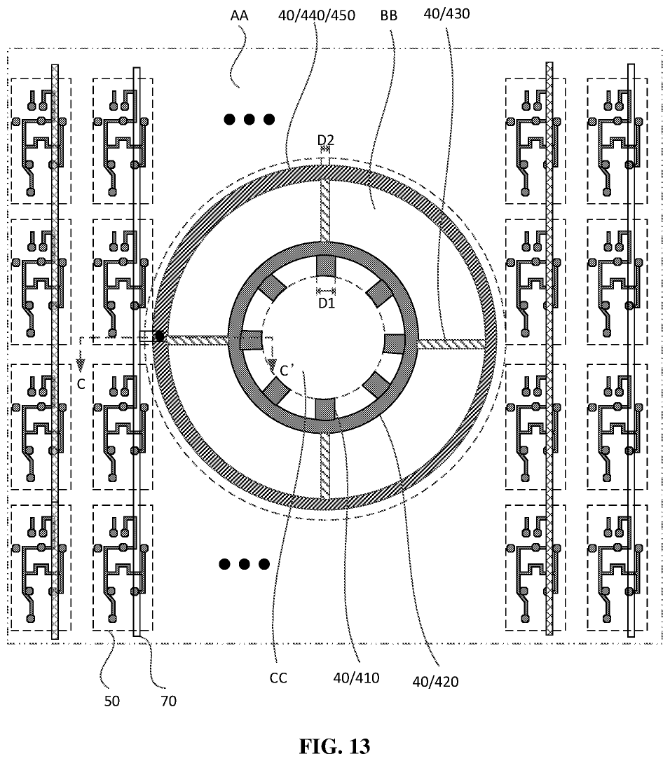

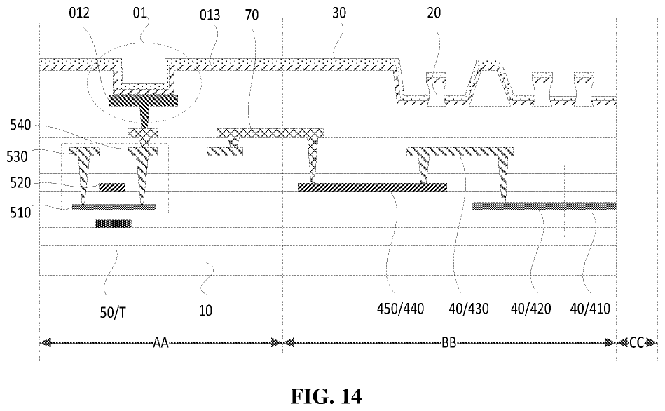

In still another embodiment, FIG. 13 is another enlarged schematic view of a region A in FIG. 1, and FIG. 14 is a cross-sectional view along a CC′ direction in FIG. 13. As shown in

FIGS. 13 and 14, the conductive structure 40 further includes a static electricity transmission line 450, the static electricity transmission line 450 is located in the display region AA and/or the isolation region BB, is electrically connected to the conductive portion 410, and includes a metal material. In the embodiment shown in FIG. 14, the conductive structure 40 includes a conductive portion 410 and a static electricity transmission line 450. The conductive portion 410 is located at a position of the conductive structure 40 facing the edge of the via region CC, and the static electricity transmission line 450 is located in the isolation region BB and located at a position of the conductive structure 40 facing away the edge of the via region CC. In other embodiments, for example, the conductive portion 410 is located in the isolation region BB and the display region AA, the static electricity transmission line 450 is located in the display region AA, or the conductive portion 410 is located in the isolation region BB, and the static electricity transmission line 450 is located in the isolation region BB and the display region AA.

Exemplarily, the conductive portion 410 is located at a position of the conductive structure 40 facing the edge of the via region CC, and the conductive portion 410 is exposed at the position of the edge of the via region CC, so that the conductive portion 410 serves as a static electricity contact point for receiving the static electricity of the via region CC. The conductive portion 410 includes a semiconductor material. Since a resistance of the semiconductor material is greater than a resistance of the metal material, that is, the conductive capability of the semiconductor material is weaker, whereby at the moment when the conductive portion 410 receives the static electricity, the heat generated on the conductive portion 410 is relatively small, and it is possible to prevent the film layer from being damaged due to excessive heat generated by the static electricity formed on the conductive portion 410. While the static electricity transmission line 450 electrically connected to the conductive portion 410 is located at a position of the conductive structure 40 facing away from the via region CC, and is used for conducting away the static electricity received by the conductive portion 410 so as to discharge the static electricity, and for example, the static electricity transmission line 450 may be disposed to include a metal material, a resistance of the metal material is less than the resistance of the semiconductor material, that is, the conductive capability of the metal material is relatively strong, and thus the static electricity received by the conductive portion 410 may be quickly conducted away through the static electricity transmission line 450, so as to accelerate the diffusion of the static electricity on the conductive structure 40, that is, the static electricity discharge capability of the conductive structure 40 is improved, and thus the risk of encapsulation failure of the display panel is reduced.

It should be noted that FIGS. 13 and 14 exemplarily illustrate that the conductive structure includes a conductive portion 410, a first connection structure 420, a connection spoke 430, a second connection structure 440 and a static electricity transmission line 450. The static electricity transmission line 450 may be reused as the second connection structure 440, the conductive portion 410 and the first connection structure 450 may include a semiconductor material, and the connection spoke 430 and the static electricity transmission line 450 may include a metal material. However, the present disclosure is not limited thereto, and those skilled in the art may set the present disclosure as required.

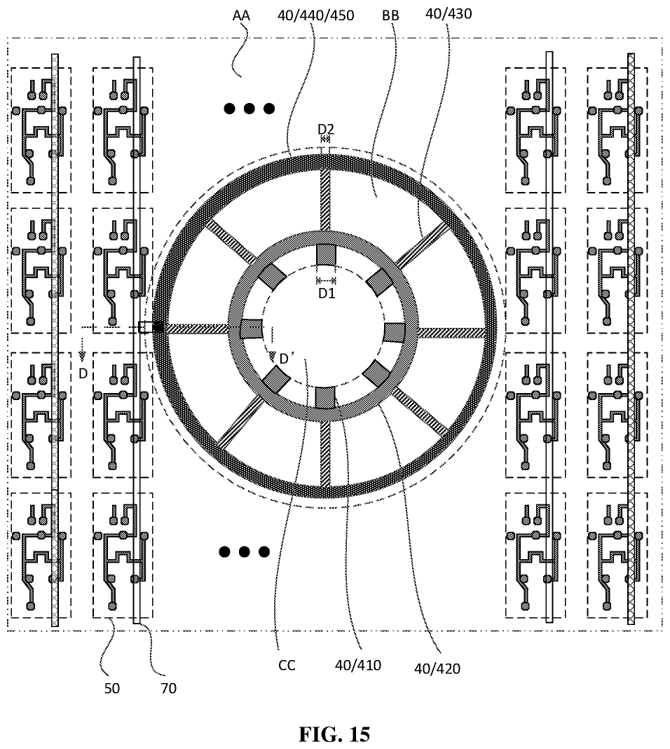

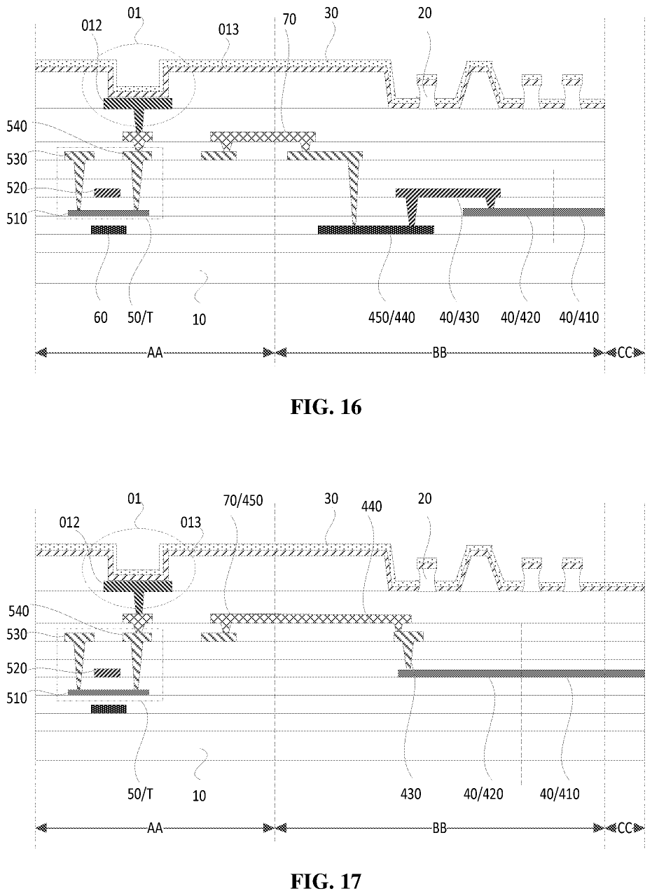

FIG. 15 is another enlarged schematic view of a region A in FIG. 1, and FIG. 16 is a cross-sectional view along a DD′ direction in FIG. 15. As shown in FIGS. 15 and 16, the display panel includes multiple pixel driving circuits 50 and a light-shielding layer 60. At least a part of the multiple pixel driving circuits 50 is located in the display region AA, the pixel driving circuit 50 is located between the cathode layer 30 and the substrate 10, and the light-shielding layer 60 is located between the pixel driving circuit 50 and the substrate 10. The pixel driving circuit 50 includes a thin-film transistor T, and the thin-film transistor T includes a channel layer 510, a gate 520, a source 530 and a drain 540. The light-shielding layer 60 is located in the display region AA, in a direction perpendicular to a plane where the substrate 10 is located, the light-shielding layer 60 overlaps with the channel layer 510, and the static electricity transmission lines 450 and the light-shielding layer 60 are disposed in a same layer.

Exemplarily, the display panel includes a driver circuit layer. The driver circuit layer is located between the substrate 10 and the cathode layer 30 and includes multiple pixel driving circuits 50 for driving the light-emitting element 01. Each pixel driving circuit 50 includes at least one thin-film transistor T. If the structure of the thin-film transistor T is the top gate structure, then in the direction in which the substrate 10 points towards the cathode layer 30, the driver circuit layer includes an active layer, a first insulation layer, a gate metal layer, a second insulation layer and a source-drain metal layer which are sequentially stacked. The channel layer 510 of the thin-film transistor T is located at the active layer of the driver circuit layer. The display panel further includes a light-shielding layer 60. The light-shielding layer is located between the pixel driving circuit 50 and the substrate 10, that is, the light-shielding layer 60 is located between the driver circuit layer and the substrate 10, in the direction perpendicular to the plane where the substrate 10 is located, the light-shielding layer 60 overlaps with the channel layer 510, and thus external light from below the substrate 10 is prevented from entering the channel layer 510 of the thin-film transistor T by means of the light-shielding layer 60, so as to avoid the generation of the leakage current.

Moreover, the static electricity transmission line 50 and the light-shielding layer 60 are disposed in a same layer, that is, the static electricity transmission line 50 and the light-shielding layer 60 disposed in the same layer each include a metal material. On the one hand, the static electricity transmission line 450 is located at a position of the conductive structure 40 facing away from the via region CC, and is used for conducting away the static electricity received by the conductive portion 410 so as to discharge the static electricity, and further, the static electricity transmission line 450 may be disposed to include a metal material, a resistance of the metal material is less than the resistance of the semiconductor material, that is, the conductivity capability of the metal material is relatively strong, and thus the static electricity received by the conductive portion 410 may be quickly conducted away through the static electricity transmission line 450 so as to accelerate the diffusion of the static electricity on the conductive structure 40, that is, the static electricity discharge capability of the conductive structure 40 is improved. On the other hand, the material used for the light-shielding layer 60 is also the metal material, and during fabrication, the static electricity transmission line 50 and the light-shielding layer 60 may be formed in a same fabrication process by using a same mask, without separately preparing a metal material at the position where the static electricity transmission line 50 is located, thereby saving the cost, reducing the number of processes, and improving the production efficiency.

FIG. 17 is another cross-sectional view along a BB′ direction in FIG. 9. As shown in FIG. 17, the display panel includes a power supply voltage line 70. The power supply voltage line 70 is at least partially located in the display region AA, the power supply voltage line 70 is located between the cathode layer 30 and the substrate 10, and the power supply voltage line 70 is configured to provide a power supply voltage. The static electricity transmission line 450 and the power supply voltage line 70 are disposed in a same layer.

Exemplarily, as shown in FIG. 17, the power supply voltage line 70 is located between the cathode layer 30 and the substrate 10, for example, between the driver circuit layer and the cathode layer 30, and at least a part of the power supply voltage line 70 is located in the display region AA, thereby supplying the power supply voltage to the display panel through the power supply voltage line 70. Moreover, the static electricity transmission line 450 and the power supply voltage line 70 are disposed in a same layer, that is, the static electricity transmission line 450 and the power supply voltage line 70 disposed in the same layer each include a metal material. On the one hand, the static electricity transmission line 450 is located at a position of the conductive structure 40 facing away from the via region CC, and is used for conducting away the static electricity received by the conductive portion 410 so as to discharge the static electricity, and further, the static electricity transmission line 450 may be disposed to include a metal material, a resistance of the metal material is less than the resistance of the semiconductor material, that is, the conductive capability of the metal material is relatively strong, and thus the static electricity received by the conductive portion 410 may be rapidly conducted away through the static electricity transmission line 450 so as to accelerate the diffusion of the static electricity on the conductive structure 40, that is, the static electricity discharge capability of the conductive structure 40 is improved. On the other hand, the material used for the power supply voltage line 70 is also the metal material, and during fabrication, the static electricity transmission line 50 and the power supply voltage line 70 maybe formed in a same fabrication process by using a same mask, without separately preparing a metal material at the position where the static electricity transmission line 50 is located, thereby saving the cost, reducing the number of processes, and improving the production efficiency.

On the basis of the above-described embodiments, with continued reference to FIG. 17, the static electricity transmission line 450 is electrically connected to the power supply voltage line 70. Exemplarily, as shown in FIG. 17, the static electricity transmission line 450 is respectively connected to the conductive portion 410 and the power supply voltage line 70, so that static electricity receive by the conductive portion 410 at a position of the via region CC is transmitted to the power supply voltage line 70 via the static electricity transmission line 450, and the power supply voltage line 70 is connected to a fixed potential so as to provide a power supply voltage for the display panel, that is, the power supply voltage line 70 may discharge the static electricity transmitted by the static electricity transmission line 450, so as to ensure that the conductive structure 40 can discharge the static electricity.

On the basis of the above-described embodiments, continuing to refer to FIGS. 2 and 3, the display panel includes multiple pixel driving circuits 50 and a light-shielding layer 60. At least a part of the pixel driving circuits 50 is located in the display region AA, the pixel driving circuit 50 is located between the cathode layer 30 and the substrate 10, and the light-shielding layer 60 is located between the pixel driving circuit 50 and the substrate 10. The pixel driving circuit 50 includes a thin-film transistor T, and the thin-film transistor T includes a channel layer 510, a gate 520, a source 530 and a drain 540. The light-shielding layer 60 is located in the display region AA, in a direction perpendicular to a plane where the substrate 10 is located, the light-shielding layer 60 overlaps with the channel layer 510. The conductive portion 410 and the light-shielding layer 60 are disposed in a same layer, and the conductive portion 410 includes a metal material.

Exemplarily, the display panel includes a driver circuit layer. The driver circuit layer includes multiple pixel driving circuits 50, at least a part of the multiple pixel driving circuits 50 is located in the display region AA and is electrically connected to the light-emitting element 01 located in the display region AA so as to drive the light-emitting element 01 to emit light for display. Each pixel driving circuit 50 includes at least one thin-film transistor T. The at least one thin-film transistor T includes a channel layer 510, a gate 520, a source 530 and a drain 540. The channel layer 510 of the thin-film transistor T is located at the active layer, the gate 520 of the thin-film transistor T is located at the gate metal layer, and the source 530 and the drain 540 of the thin-film transistor T are located at a source-drain metal layer. The display panel further includes a light-shielding layer 60, the light-shielding layer is located between the pixel driving circuit 50 and the substrate 10, and the light-shielding layer 60 overlaps with the channel layer 510 in the direction perpendicular to the plane where the substrate 10 is located, so that external light from below the substrate 10 is prevented from entering the channel layer 510 of the thin-film transistor T by means of the light-shielding layer 60, so as to avoid the generation of the leakage current. Moreover, the conductive portion 410 and the light-shielding layer 60 are disposed in a same layer, that is, the conductive portions 410 and the light-shielding layer 60 disposed in the same layer each include a metal material, and a resistance of the metal material is less than the resistance of the semiconductor material, that is, the conductive capability of the metal material is relatively strong, and the conductive portion 410 serves as a static electricity contact point for receiving static electricity of the via region CC. The conductive portion 410 is disposed to include the metal material, the conductive capability of the conductive portion 410 may be made stronger, that is, the static electricity receiving capability of the conductive portion 410 is enhanced, so that the conductive portion 410 receives more static electricity generated from the side of the substrate 10 in the via region CC, thereby further reducing the amount of static electricity finally reaching the cathode layer 30, improving the static electricity discharge capability of the conductive structure 40, and thus reducing the risk of the encapsulation failure of the display panel. Moreover, the material used in the light-shielding layer 60 is also the metal material, during fabrication, the conductive portion 410 and the light-shielding layer 60 maybe formed in a same fabrication process by using a same mask, without separately preparing a semiconductor material at the position where the conductive portion 410 is located, thereby saving the cost, reducing the number of processes, and improving the production efficiency.

Optionally, with continued reference to FIGS. 1 to 3, the display panel further includes an organic light-emitting material layer 013, in a direction perpendicular to a plane where the substrate 10 is located, the organic light-emitting material layer 013 is located between the cathode layer 30 and the conductive structure 40, and the organic light-emitting material layer 013 is disconnected by the isolation pillar 20.

Exemplarily, as shown in FIGS. 1 to 3, the light-emitting element 01 is disposed in display region AA, and the light-emitting element 01 includes a cathode layer 30, a pixel electrode 012, and an organic light-emitting material layer 013 between the cathode layer 30 and the pixel electrode 012. The drain 540 of the thin-film transistor T is connected to the pixel electrode 012. The organic light-emitting material layer 013 may include film layers such as a hole injection layer, a hole transport layer, a light-emitting layer, an electron transport layer and an electron injection layer, which are laminated. For example, when no voltage is applied to the cathode layers 30 and the pixel electrode 012, the light-emitting element 01 does not emit light. When the voltage is applied to the cathode layer 30 and the pixel electrode 012, a layer of the pixel electrode 012 injects holes into the hole injection layer, and the cathode layer 30 injects electrons into the electron injection layer. The holes and the electrons are recombined in the light-emitting layer to form light exciton and emit light by radiation, so that the light-emitting element 01 may emit light and display normally. The via region CC has no light-emitting element 01 and is disposed to be transparent for placing devices such as a camera or a sensor, the isolation region BB is located between the display region AA and the via region CC, and the isolation region CC at least partially surrounds the via region CC, and further, the display region AA and the via region CC are isolated through the isolation region 300.

Exemplarily, as shown in FIG. 3, the isolation region BB includes multiple isolation pillars 20, the multiple isolation pillars 20 are disposed on a side of the substrate 10 and are located between the display region AA and the via region CC, so that at least one organic light-emitting material layer 013 of the display region AA may be disconnected at the isolation region BB by means of the isolation pillars. The multiple isolation pillars 20 are arranged in a direction in which the via region CC points towards the display region AA, so that the external moisture and oxygen can be prevented from permeating into the display region AA through the boundary of the via region CC so as to erode the light-emitting element 01, whereby the blocking effect of the isolation region BB with respect to moisture and oxygen is improved, and thus the reliability of the display panel is improved.

Optionally, on the basis of the above-described embodiments, with continued reference to FIG. 3, the substrate 10 is a flexible substrate, the display panel further includes an ultra-clean layer 80, and the ultra-clean layer 80 is located on a side of the substrate 10 facing away from the conductive structure 40. Exemplarily, the substrate 10 is a flexible substrate, and the flexible substrate may be a flexible polymer material, for example, any one of polyimide (PI), polycarbonate (PC), polyethylene terephthalate (PET) or polyethylene naphthalate (PEN) may be selected so as to ensure that the display panel may be bent. A side of the substrate 10 facing away from the conductive structure 40 further includes an ultra-clean layer 80, and a support layer may also be provided between the ultra-clean layer 80 and the substrate 10. Therefore, the display panel may be supported by the support layer, and buffering, shielding and heat dissipation effects may be achieved by the ultra-clean layer 80.

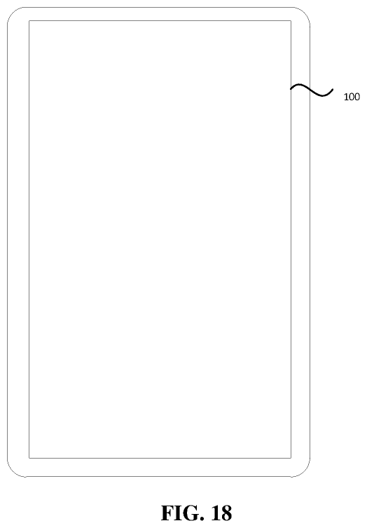

Based on the above inventive concept, an embodiment of the present disclosure further provides a display device. FIG. 18 is a schematic structural view of a display device according to an embodiment of the present disclosure. As shown in FIG. 18, the display device includes the display panel 100 in the above-described embodiments. The display device includes the display panel 100 in any one of the embodiments of the present disclosure; therefore, the display device provided in the embodiments of the present disclosure has the corresponding beneficial effect of the display panel 100 provided in the embodiments of the present disclosure, which will not be repeated herein. Exemplarily, the display device may be an electronic device such as a mobile phone, a computer, a smart wearable device (such as, a smart watch), and a vehicle-mounted display device, which is not limited in the embodiments of the present disclosure.

It should be noted that the above are merely preferred embodiments of the present disclosure and the technical principles applied herein. It should be understood by those skilled in the art that the present disclosure is not limited to the particular embodiments described herein. For those skilled in the art, various apparent modifications, readjustments and substitutions may be made without departing from the scope of protection of the present disclosure. Therefore, although the present disclosure has been described in detail through the above embodiments, the present disclosure is not limited to the above embodiments and may include more other equivalent embodiments without departing from the concept of the present disclosure. The scope of the present disclosure is determined by the scope of the appended claims.

What is claimed is:

1. A display panel, comprising:
a display region, an isolation region and a via region, wherein the isolation region at least partially surrounds the via region, the display region at least partially surrounds the isolation region;
a substrate;
an isolation pillar, which is located in the isolation region and on a side of the substrate, and comprises a metal material;
a cathode layer, which is located on a side of the isolation pillar facing away from the substrate and is disconnected by the isolation pillar; and
a conductive structure, which is located between the cathode layer and the substrate, and comprises at least one conductive portion, wherein the at least one conductive portion is at least partially located in the isolation region and overlaps with an edge of the via region.

2. The display panel of claim 1, wherein the conductive structure comprises a plurality of conductive portions and a first connection portion, wherein,
the plurality of conductive portions are arranged at intervals along an extension direction of the edge of the via region; and
the first connection portion is located in the isolation region, is located on a side of the plurality of the conductive portions facing away from the via region, and is electrically connected to the plurality of conductive portions.

3. The display panel of claim 2, wherein each conductive portion of the plurality of conductive portions comprises a conductive connection end and a conductive tip end, and the conductive connection end connects the conductive tip end and the first connection portion; and
in a direction perpendicular to an extension direction of the each conductive portion, a width of the conductive tip end is less than a width of the conductive connection end.

4. The display panel of claim 2, wherein the first connection portion extends in the extension direction of the edge of the via region and comprises a first notch.

5. The display panel of claim 2, wherein the conductive structure further comprises a plurality of connection spokes and a second connection portion; and
the second connection portion at least partially surrounds the first connection portion, and the plurality of connection spokes connect the first connection portion and the second connection portion.

6. The display panel of claim 5, wherein in a direction perpendicular to an extension direction of a conductive portion of the plurality of conductive portions, a width of the conductive portion is a first width;
in a direction perpendicular to an extension direction of a connection spoke of the plurality of connection spokes, a width of the connection spoke is a second width; and
the first width is greater than the second width.

7. The display panel of claim 5, wherein the second connection portion extends in the extension direction of the edge of the via region and comprises a second notch.

8. The display panel of claim 1, wherein the conductive structure comprises one conductive portion of the at least one conductive portion, and the one conductive portion extends in an extension direction of the edge of the via region.

9. The display panel of claim 1, wherein each of the at least one conductive portion comprises a semiconductor material.

10. The display panel of claim 9, comprising a plurality of pixel driving circuits, wherein at least a part of the plurality of pixel driving circuits is located in the display region, and the plurality of pixel driving circuits are located between the cathode layer and the substrate; and
in a direction perpendicular to a plane where the substrate is located, and the at least one conductive portion is between the substrate and the plurality of pixel driving circuits.

11. The display panel of claim 9, comprising a plurality of pixel driving circuits, wherein at least a part of the plurality of pixel driving circuits is located in the display region, and the plurality of pixel driving circuits are located between the cathode layer and the substrate; and
each of the plurality of pixel driving circuits comprises a thin-film transistor, the thin-film transistor comprises a channel layer, a gate, a source and a drain, and the at least one conductive portion and the channel layer are disposed in a same layer.

12. The display panel of claim 9, wherein the conductive structure further comprises a static electricity transmission line, the static electricity transmission line is located in at least one of the display region or the isolation region, is electrically connected to the at least one conductive portion, and comprises a metal material.

13. The display panel of claim 12, comprising a plurality of pixel driving circuits and a light-shielding layer, at least a part of the plurality of pixel driving circuits is located in the display region, the plurality of pixel driving circuits are located between the cathode layer and the substrate, and the light-shielding layer is located between the plurality of pixel driving circuits and the substrate;
each of the plurality of pixel driving circuits comprises a thin-film transistor, the thin-film transistor comprises a channel layer, a gate, a source and a drain, the light-shielding layer is located in the display region, in a direction perpendicular to a plane where the substrate is located, the light-shielding layer overlaps with the channel layer; and
the static electricity transmission line and the light-shielding layer are disposed in a same layer.

14. The display panel of claim 12, comprising a power supply voltage line, wherein the power supply voltage line is at least partially located in the display region, is located between the cathode layer and the substrate, and is configured to provide a power supply voltage; and
the static electricity transmission line and the power supply voltage line are disposed in a same layer.

15. The display panel of claim 14, wherein the static electricity transmission line is electrically connected to the power supply voltage line.

16. The display panel of claim 1, comprising a plurality of pixel driving circuit and a light-shielding layer, at least a part of the plurality of pixel driving circuits is located in the display region, the plurality of pixel driving circuits are located between the cathode layer and the substrate, and the light-shielding layer is located between the plurality of pixel driving circuits and the substrate;
the pixel driving circuit comprises a thin-film transistor, the thin-film transistor comprises a channel layer, a gate, a source and a drain, the light-shielding layer is located in the display region, in a direction perpendicular to a plane where the substrate is located, the light-shielding layer overlaps with the channel layer; and
the at least one conductive portion and the light-shielding layer are disposed in a same layer, and the at least one conductive portion comprises a metal material.

17. The display panel of claim 1, further comprising an organic light-emitting material layer, in a direction perpendicular to a plane where the substrate is located, the organic light-emitting material layer is located between the cathode layer and the conductive structure, and the organic light-emitting material layer is disconnected by the isolation pillar.

18. The display panel of claim 17, wherein the substrate is a flexible substrate, the display panel further comprises an ultra-clean layer located on a side of the substrate facing away from the conductive structure.

19. A display device, comprising a display panel, wherein the display panel comprises:
a display region, an isolation region and a via region, wherein the isolation region at least partially surrounds the via region, the display region at least partially surrounds the isolation region;
a substrate;
an isolation pillar, which is located in the isolation region and on a side of the substrate, and comprises a metal material;
a cathode layer, which is located on a side of the isolation pillar facing away from the substrate and is disconnected by the isolation pillar; and
a conductive structure, which is located between the cathode layer and the substrate, and comprises at least one conductive portion, wherein the at least one conductive portion is at least partially located in the isolation region and overlaps with an edge of the via region.

20. The display device of claim 19, wherein the conductive structure comprises a plurality of conductive portions and a first connection portion, wherein,
the plurality of conductive portions are arranged at intervals along an extension direction of the edge of the via region; and
the first connection portion is located in the isolation region, is located on a side of the plurality of the conductive portions facing away from the via region, and is electrically connected to the plurality of conductive portions.
